(19) United States
(12) Patent Application Publication
(10) Pub. No.: US 2026/0023315 A1
(43) Pub. Date: Jan. 22, 2026

(54) METHOD FOR ANALYSING A MASK FOR LITHOGRAPHY

(71) Applicant: Carl Zeiss SMT GmbH, Oberkochen (DE)

(72) Inventors: Philipp Schoeppe, Jena (DE); Kay Dornbusch, Jena (DE); Thomas Zeuner, Jena (DE)

(21) Appl. No.: 19/266,514

(22) Filed: Jul. 11, 2025

(30) Foreign Application Priority Data
Jul. 18, 2024 (DE) 102024120297.1

(51) Int. Cl. G03F 1/22; G01B 11/02; G01N 21/956

(52) U.S. Cl. CPC G03F 1/22; G01B 11/02; G01N 21/956; G01N 2021/95676

(57) ABSTRACT

A method for analysing a mask for lithography, comprising: aligning an aerial image of the mask and a mask design of the mask to form a superimposition of the aerial image and the mask design, wherein a CD threshold value determining region and a CD measuring region are positioned within the aerial image; determining a CD threshold value in the CD threshold value determining region using the superimposition of the aerial image and the mask design; and measuring a critical dimension, CD, in the CD measuring region using the aerial image and the determined CD threshold value. Further disclosed is a corresponding computer program, device and system.

### CROSS REFERENCE TO RELATED APPLICATIONS

The present application claims the priority of the German patent application 10 2024 120 297.1 filed on Jul. 18, 2024, the content of which is fully incorporated by reference herein.

### TECHNICAL FIELD

This disclosure relates to a method for analysing a mask for lithography, a corresponding computer program, a corresponding device and a corresponding system.

### BACKGROUND

Lithographic methods and devices have long been known. By way of example, lithography is used in semiconductor technology in order to image structures and shape them in a targeted manner by way of subsequent processes.

Lithography typically involves using a mask having a pattern that is intended to create a desired structure. By way of example, the mask can be exposed for this purpose, wherein an image of the pattern of the mask is generated in a desired imaging plane. As a result, an intensity distribution according to the image of the pattern is generated in the imaging plane. This intensity distribution can then interact with the constraints in the imaging plane, such that the desired structure can be produced.

In this regard, lithography usually involves exposure of an exposure-sensitive layer (e.g. a photoresist layer on a wafer) by means of the mask, wherein the imaging plane of the mask can then lie in the region of the exposure-sensitive layer. The intensity distribution of the image of the pattern of the mask results in physically and/or chemically locally different reaction of the exposure-sensitive layer. The exposure can then be followed by developing the exposure-sensitive layer (e.g. using a chemical solvent), such that resist structures are produced according to the image of the pattern of the mask. The resist structures produced can subsequently be processed further (e.g. by means of etching processes to create corresponding structures on the wafer).

Faults should be avoided during lithography owing to the concomitant possibility of structures produced in a faulty manner, which should be avoided from a technical standpoint.

A fault may be e.g. a defect of the mask itself. In this regard, the defect may be a defective pattern on the mask (e.g. a defective pattern element) which has an unwanted spatial configuration. As a result, during the exposure of the mask, a faulty imaging may be created in the imaging plane, which might subsequently lead to the production of a faulty structure. Mask faults of this type are usually unavoidable during the production of the masks, owing to the technical complexity during the manufacture of the masks.

Furthermore, the lithography result usually depends on the lithographic parameters used (e.g. on exposure parameters). Faults in the image of the mask may thus vary depending on one or more lithographic parameters. A fault during lithography may be in this case e.g. a faulty measurement in the intensity profile of the image of the mask. Faults of this type are not always readily foreseeable owing to the complex interactions during lithography.

Against this background, during lithography, it is customary to analyse masks (e.g. with regard to the lithography method carried out with them) in order to avoid, find and/or correct faults during lithography. By way of example, inspection systems for analysing masks for lithography are known for this purpose. Some mask inspection systems may e.g. generate the optical constraints present during the actual lithography method pertaining to the mask, and carry out an analysis of the imaging of the mask depending on various lithographic parameters. For this purpose, mask inspection systems of this type may be designed as a microscope, making it possible to create optical constraints like those in the actual lithography. In particular, mask inspection systems of this type may analyse a so-called aerial image of the mask depending on various lithographic parameters. What is thus implemented is as it were an optical simulation of the lithography method, without the need for the actual lithography method to take place. In this case, mask inspection systems of this type are usually significantly more compact than the optical systems employed for the actual lithography method, and so the use as an analysis tool can be reliably ensured.

By way of example, known analysis methods are however not always suitable for all current or future purposes of use. There is thus a high degree of freedom in respect of use and/or design of masks, in particular regarding the technology produced therewith. In the field of lithography, which is constantly undergoing further development, there is thus a need for corresponding further development of analysis methods.

Therefore, it is an object of the present disclosure to improve the analysing of masks for lithography.

### SUMMARY

In general, in one aspect, disclosed is a method for analysing a mask for lithography, comprising: aligning an aerial image of the mask and a mask design of the mask to form a superimposition of the aerial image and the mask design; wherein a CD threshold value determining region and a CD measuring region are positioned within the aerial image; determining a CD threshold value in the CD threshold value determining region using the superimposition of the aerial image and the mask design; measuring a critical dimension CD in the CD measuring region using the aerial image and the determined CD threshold value.

As described herein, the term aerial image is known in the field of lithography. An aerial image corresponds to the optical imaging of a mask in a specific imaging plane given a specific set of lithographic parameters. The aerial image can represent e.g. an intensity profile corresponding to the imaging of the mask in the imaging plane during lithography.

The mask design is likewise a known term from the field of lithography. The desired target dimensions of the mask are stored in the mask design. The mask design thus shows the ideal profile of the mask, and undesired production-dictated and/or lithographic faults are indeed not stored in the mask design. For example, the (ideal) mask design in a simple case can be defined by way of two (colour) codings (e.g. light and dark). In such a case, e.g. a first colour coding (e.g. light) may denote a presence of absorbing material on the mask, and a second colour coding (e.g. dark) different from that may denote an absence of absorbing material on the mask. Consequently, e.g. the profile of pattern elements of the mask that are formed by absorbing material can be represented in the mask design. Furthermore, the colour codings can also be used for identifying reflective or respectively non-reflective locations of the mask, or for identifying transmissive or respectively non-transmissive locations of the mask.

In summary, the ideal desired profile of the pattern of the mask can thus be represented in the mask design.

The mask described herein can be designed for example for a lithographic method in which the dimensions of the pattern of the mask are also intended to be present correspondingly in the aerial image in a desired imaging plane. In such a case, the dimensions on the mask should thus also ideally be present in the aerial image of the mask. During lithography with the mask, for example, the exposed resist structures would thus have substantially distances similar to those on the mask (although the resist structures may e.g. also deviate by a specific scaling factor).

Furthermore, the term critical dimension (CD) is an established term in the field of lithography. In this regard, the CD denotes in principle a characteristic dimension. The CD functions here as a characteristic variable that can be taken as a basis for carrying out a technical assessment (e.g. with regard to the technical desired dimension of the CD).

By way of example, the CD may be a characteristic dimension in the aerial image of the mask, e.g. a width of a characteristic line in the aerial image of the mask.

By way of example, the CD may also be a characteristic width of a line in the mask design of the mask, e.g. a width of a pattern element in the mask design.

By way of example, the CD may also be a characteristic dimension on the mask itself, e.g. a dimension of a width of a pattern element on the mask.

In accordance with the first aspect, one approach involves performing a superimposition of the aerial image and the mask design of the mask. The superimposition allows a spatial superimposition of the aerial image and the mask design to be present, such that e.g. a point (e.g. a pixel) in the mask design can also be assigned a corresponding point (e.g. pixel) in the aerial image. Consequently, a parameter of the mask design (e.g. a colour coding) can thus also be assigned a corresponding parameter of the aerial image (e.g. a corresponding intensity).

The superimposition can be effected in such a way that corresponding points are superimposed, thus making it possible to technically deduce in principle which structure of the mask design causes which intensity profile in the aerial image. By way of example, in the superimposition, firstly it is possible to technically deduce the intensity profile of the aerial image, and furthermore the colour-coded structures are likewise technically deducible from the mask design. In this case, the superimposition can be present in a data set, for example, wherein firstly spatial coordinates are given, which are respectively assigned in one instance the parameters of the aerial image and in one instance the corresponding parameters of the mask design. By way of example, the superimposition of a location x,y can store in one instance an intensity of the aerial image I_{x,y} and in one instance a colour coding C_{x,y} of the corresponding location of the mask design.

However, the superimposition need not necessarily be a superimposition in an image or a data set. The superimposition can also simply be an assignment of the parameters of the mask design to the parameters in the aerial image for the corresponding locations. By way of example, a location x,y can be assigned in one instance an intensity of the aerial image I_{x,y} and in one instance a colour coding C_{x,y} of the corresponding location of the mask design, thus resulting functionally in a superimposition.

In accordance with the first aspect, a CD threshold value determining region and a CD measuring region are positioned within the aerial image. In this case, the CD threshold value determining region can differ from the CD measuring region. It is possible for example that the CD threshold value determining region and the CD measuring region do not overlap.

The method involves determining a CD threshold value in the CD threshold value determining region using the superimposition of the aerial image and the mask design. The information from the aerial image and the mask design can be used in this step of determining the CD threshold value.

It should be mentioned that the term CD threshold value is known in the field of lithography. This is, therefore, usually a threshold (e.g. an intensity threshold) as of which a critical dimension (CD) begins or ends. By way of example, the CD threshold value is determined for characteristic regions in the aerial image. For example, the CD threshold value can indicate whether or not, proceeding from this threshold of the intensity, the exposure-sensitive resist is developed during lithography.

In accordance with the method, the superimposition of mask design and aerial image can be used (as described herein) for the determination of the CD threshold value.

Furthermore, determining the CD threshold value is followed by measuring a critical dimension, CD, in the CD measuring region using the aerial image and the determined CD threshold value.

In this regard, the determined CD threshold value then affords information about the point as of which a CD begins or ends. This information can be used for the CD measuring region in order to measure there a CD to be examined (using the aerial image). By way of example, a dimension of an arbitrary imaging of a mask structure can be measured as CD in the CD measuring region.

The approach described herein thus firstly enables the CD threshold value to be determined in an optimized manner in a first region (the CD threshold value determining region). By way of example, this first region may be better suited to a determination of the CD threshold value than some other region. Afterwards, a second region (the CD measuring region) can then be examined with the aid of the previously determined CD threshold value. The second region may be e.g. less well suited to determining a CD threshold value.

In one example, the method can furthermore comprise: determining a target CD in the CD measuring region using the mask design; comparing the measured CD with the determined target CD. In accordance with this step, the mask design with the target CD can be used firstly to determine the dimension of the mask structure from the CD measuring region in the ideal case on the mask.

Regarding the example above, two items of information are thus present. Firstly, the measured CD, which is a characteristic dimension of an imaging of a mask structure in the CD measuring region of the aerial image. Secondly, the target CD, which is the corresponding characteristic dimension of the same mask structure in the corresponding measuring region of the mask design.

In an ideal case, the target CD of the mask structure in the mask design would also be the corresponding CD of this mask structure on the mask. In this ideal case, the measured CD of the imaging of this mask structure would then exactly correspond to the target CD (or the measured CD would have an expected deviation from the target CD). However, such an ideal case cannot always be provided.

Therefore, comparing the measured CD with the determined target CD can comprise for example determining the deviation between measured CD and target CD. That can then be taken as a basis for making a technical assessment for the lithography.

In one example, the method can furthermore comprise: positioning the CD threshold value determining region and the CD measuring region within the aerial image; wherein the CD threshold value determining region is positioned such that a non-defective location of the mask is present in the CD threshold value determining region; wherein the CD measuring region is positioned such that a defective location of the mask is present in the CD measuring region; wherein measuring the critical dimension (CD) comprises measuring a dimension of the defective location.

In summary, a defect may thus be present in the CD measuring region, wherein the CD of the defect is measured. By contrast, the CD threshold value determining region may have no defect, such that the determination of the CD threshold value is not adversely affected.

In this regard, determining the CD threshold value in the CD threshold value determining region can be effected by way of a dimension of an imaging of a non-defective structure.

In one example, positioning the CD threshold value determining region and the CD measuring region within the aerial image can be effected manually by an operator. By way of example, the operator can position the CD measuring region manually around a defective location found previously. For example, the defective location may have been (automatically) determined previously, wherein the operator optimizes the CD measuring region around the defective location by manual adjustment. Furthermore, the operator can define the CD threshold value determining region around a non-defective location found previously.

In one example, for positioning the CD threshold value determining region and the CD measuring region within the aerial image, firstly determining the defective location and the non-defective location can be effected manually by an operator. This can be recognized e.g. by way of empirical values on the part of the operator and/or by way of a deviation in the aerial image.

In one example, after positioning the CD threshold value determining region and the CD measuring region, the following steps can be effected automatically: aligning the aerial image of the mask and the mask design; determining the CD threshold value; measuring the critical dimension.

By way of example, for the method, the following step can be effected manually by the operator: Positioning the CD threshold value determining region and the CD measuring region within the aerial image; while the following steps are effected automatically: aligning the aerial image of the mask and the mask design; determining the CD threshold value; measuring the critical dimension.

The method of the first aspect can thus constitute a semiautomatic process. In the context of the method, it is thus up to the operator to define the CD threshold value determining region and the CD measuring region. The remaining analysis steps of the method are then effected automatically (as described herein). Consequently, the operator firstly has a high degree of freedom on the basis of their technical expertise as to what locations or what size are/is suitable for the CD threshold value determining region and for the CD measuring region. However, the further analysis steps then do not require further manual inputs, thus reducing time and complexity during the analysis.

In one example, after positioning the CD threshold value region and the CD measuring region, the following steps can furthermore be effected automatically: determining the target CD in the CD measuring region; comparing the measured CD with the determined target CD.

By way of example, the following step can be effected manually by the operator: positioning the CD threshold value determining region and the CD measuring region within the aerial image; while the following steps are effected automatically: aligning the aerial image of the mask and the mask design; determining the CD threshold value; measuring the critical dimension; determining the target CD in the CD measuring region; comparing the measured CD with the determined target CD.

In one example, after positioning the CD threshold value determining region and the CD measuring region, manually confirming the positioning can the effected by the operator, wherein the automatic steps are started by the confirming. It is thus possible to ensure a targeted trigger for executing the automatic steps.

In one example, determining the CD threshold value can comprise: determining at least one transition position of the mask design at which there is a transition from an imaging structure to a non-imaging structure of the mask; determining an intensity of the aerial image at the transition position; wherein the CD threshold value is at least partly based on the intensity of the aerial image at the at least one transition position.

A structure transition in the mask design is thus used for the determination of the CD threshold value. This approach is based on the assumption that the structure transition in the mask design is also correspondingly realized in the aerial image. By way of example, this may be assumed e.g. if the CD threshold value determining region comprises a non-defective location (as described herein).

In one example, the CD threshold value can correspond to the intensity of the aerial image at the at least one transition position. If a specific intensity is present e.g. at the transition position x,y at which an imaging structure transitions to a non-imaging structure, this intensity is assumed as the CD threshold value.

In one example, determining the CD threshold value can comprise: determining a first intensity profile of the aerial image along a first line in the CD threshold value determining region; wherein along the first line there is at least one transition position of the mask design at which there is a transition from an imaging structure to a non-imaging structure of the mask; determining a first CD threshold value at least partly on the basis of an intensity of the first intensity profile at the at least one transition position of the first line.

The intensity profile enables a better evaluation for determining the CD threshold value. In the field of lithography, such an intensity profile for the determination of the CD threshold value may also be referred to as a “slice”.

By way of example, along the first line there may also be two transition positions of the mask design (e.g. a first transition from an imaging structure to a non-imaging structure, and a subsequent second transition from the non-imaging structure to a further imaging structure). Consequently, two CD threshold values can also be determined for the first intensity profile along the first line. These values can be averaged to form a CD threshold value, for example.

In one example, determining the CD threshold value can furthermore comprise: determining a second intensity profile of the aerial image along a second line in the CD threshold value determining region; wherein the second line differs from the first line; wherein along the second line in the mask design there is at least one transition position of the mask design at which there is a transition from an imaging structure to a non-imaging structure of the mask; determining a second CD threshold value at least partly on the basis of an intensity of the second intensity profile at the at least one transition position of the second line.

The CD threshold value can thus also be based on two different intensity profiles.

In one example, determining the CD threshold value can furthermore comprise: calculating an average value from the first and second CD threshold values, wherein the average value is determined as the CD threshold value. In this example, therefore, firstly the first CD threshold value is determined by way of the first intensity profile, and the second CD threshold value is determined by way of the second intensity profile. Afterwards, these two CD threshold values are averaged, thus resulting in an (averaged) CD threshold value. The latter can then be used for the CD measurement.

The averaging of the CD threshold value on the basis of two different intensity profiles makes it possible to average fluctuations in the aerial image, thereby enabling better determination of a representative CD threshold value. Consequently, the CD measurement, too, can be correspondingly improved.

In one example, determining the CD threshold value can comprise: determining intensity profiles of the aerial image along at least three lines in the CD threshold value determining region; wherein the lines differ from one another; wherein in each case along a line in the mask design there is at least one transition position of the mask design at which there is a transition from an imaging structure to a non-imaging structure of the mask; determining a respective CD threshold value for a respective line at least partly on the basis of an intensity of the respective intensity profile at the at least one transition position of the respective line.

The CD threshold value can thus also be based on three or more different intensity profiles. This can further improve the determination of a representative CD threshold value.

In one example, determining the CD threshold value can comprise determining intensity profiles of the aerial image at least along four, five, ten, twenty or one hundred lines in the CD threshold value determining region.

In one example, determining the CD threshold value can furthermore comprise: calculating an average value from the respective CD threshold values of the different lines, wherein the average value is determined as the CD threshold value. By way of example, firstly a first CD threshold value can be determined by way of a first intensity profile, a second CD threshold value can be determined by way of a second intensity profile, and a third CD threshold value can be determined by way of a third intensity profile, wherein optionally further CD threshold values can be determined by way of further intensity profiles. Afterwards, the different CD threshold values thus determined can be averaged, thus resulting in an (averaged) CD threshold value. The latter can then be used for the CD measurement.

In one example, measuring the critical dimension, CD, can comprise: determining a distance between two characteristic points of the aerial image in the CD measuring region, wherein the intensity at the points substantially corresponds to the CD threshold value. This distance can be e.g. a line width of an imaging of a line structure.

In one example, the mask can comprise a single-die mask, such that a die can be imaged in an imaging plane during a lithographic exposure of the mask. By way of example, a single-die mask can have the structure of a layer of exactly one die as mask structure. The structures for two or more chips (or for two or more dies) are usually applied on a mask since appropriate area is available. In the case of a single-die mask, however, one comparatively large chip or comparatively large die can be involved, and so only the structures of exactly one single die or one single chip can be applied on account of the area limitation of the mask. A periodicity of structures with regard to the overall architecture of a die is therefore not provided in a single-die mask. In such a case, there is then e.g. also no reference on the mask to a die having the same architecture, since a further die architecture is not present.

By way of example, masks with a plurality of die structures would provide at least one architecture for a first die and a second die on the mask. If e.g. a defective location is then present in the first die, a non-defective location corresponding thereto on the second die could be used as reference. For example, in such a case, the first die could have, in the bottom left corner, a specific contact hole that is defective, wherein in the second (identically constructed) die, precisely this contact hole in the bottom left corner could then be taken as reference if this corresponding contact hole were non-defective. By way of example, in this case, the non-defective reference of the corresponding die could then be used for the determination of a CD threshold value in order to measure the defective location of the defective die.

In the case of single-die masks this approach cannot work, however, since there is no further die reference. Furthermore, it also cannot always be assumed that there are repeating structures for a die architecture (e.g. two identical contact holes on a die structure). For single-die masks, the method described herein is therefore advantageous with regard to a non-defective reference. Thus, in accordance with the method described herein, applied to a single-die mask, use is made of a CD threshold value determining region comprising a non-defective location, wherein this reference lies on the same die since, ultimately, a single-die mask is involved. Consequently, for a single-die mask as well, it is possible to reliably use a reference for determining the CD threshold value in order to measure the defective location in a targeted manner.

In one example, comparing the measured CD with the determined target CD can be followed by automatically generating a report representing a summary of the method. By way of example, at least one of the following can be indicated in the report: the CD threshold value, the measured CD, the target CD, the deviation between the measured CD and the target CD, the position of the CD threshold value determining region, the position of the CD measuring region.

In one example, the mask can comprise a mask for DUV lithography, i.e. e.g. for an illumination wavelength of 365 nm, 248 nm or 193 nm, and/or EUV lithography, e.g. for an illumination wavelength of 13.5 nm.

A second aspect relates to a computer program comprising instructions for executing a method of the first aspect.

The instructions, for example, when they are executed by one or more processors, can cause the one or more processors to send control commands in order to cause a device to implement the method of the first aspect. The control commands can be sent e.g. to a computer and/or a computing unit of a device.

The second aspect also relates to a non-transitory medium (e.g. a memory) having the computer program comprising instructions for executing a method of the first aspect.

A third aspect relates to a device for analysing a mask comprising a computing unit, wherein the computing unit is configured to execute a method of the first aspect.

The device can be a computer, for example.

By way of example, the device can also comprise a mask inspection apparatus or a mask inspection system pertaining to lithography. For example, the mask inspection apparatus (or mask inspection system) can be designed to generate the optical constraints during lithography, such that it is possible to generate an aerial image of the mask as in the case of a lithographic method.

In one example, the device can comprise a memory, wherein the memory comprises the computer program of the second aspect; wherein the computing unit is configured to execute the computer program.

A fourth aspect relates to a system for analysing a mask for lithography, comprising: a first unit for generating an aerial image of the mask, which aerial image can be present during the lithography of the mask; a second unit for storing a mask design of the mask; a third unit comprising a computing unit, wherein the computing unit is configured to execute a method of the first aspect; wherein the first unit and the second unit are each communicatively coupled to the third unit, such that the third unit can receive and/or retrieve the aerial image and the mask design.

In one example, the third unit can furthermore comprise a memory, wherein the memory comprises the computer program of the second aspect; wherein the computing unit is configured to execute the computer program.

The explanations described herein with regard to the method or the computer program can also apply, mutatis mutandis, to the devices, apparatuses and/or system described herein (and also vice versa).

### DESCRIPTION OF DRAWINGS

Exemplary embodiments and variants are explained in greater detail below with reference to the drawing, in which:

FIGS. 1A and 1B show by way of example basic concepts of the prior art for the analysis of masks.

FIG. 2 shows an exemplary method from the prior art for analysing a mask by means of a CD measurement.

FIG. 3 schematically shows the method from the prior art from FIG. 2.

FIG. 4 shows an exemplary method for analysing a mask in accordance with the disclosure described herein.

FIG. 5 schematically shows the method from FIG. 4.

### DETAILED DESCRIPTION

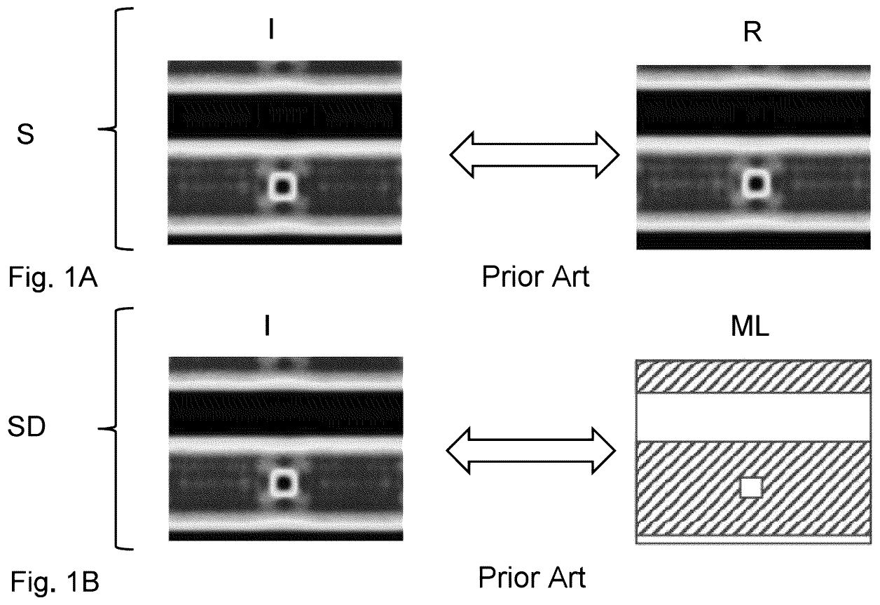

FIGS. 1A and 1B show by way of example basic concepts of the prior art for the analysis of masks. As described herein, mask inspection systems are known in the field of lithography. A mask inspection system can be used to analyse a mask for lithography under the optical constraints which would also be present during the actual lithography method using the mask. In particular, mask inspection systems can be used to analyse the aerial image of the mask (the term aerial image here is also a known technical term). The aerial image can make possible e.g. an analysis of the dimensions of imagings of specific mask structures, without a lithography process having to take place. In this regard, it is known to use mask inspection systems to perform measurements of critical dimensions, usually referred to as CD measurement (as described herein).

Mask inspection systems are usually used to perform CD measurements in the region of a purported defect in order to check whether this region fulfils a predefined specification in the context of lithography. By way of example, a defective region on the mask (e.g. a defective pattern element) may cause a defective region in the aerial image, such that the CD in the aerial image at a corresponding defective location is not within specification. By way of example, the CD measurement can therefore be performed for a defective region before and/or after the correction of the defective region in order to make a technical statement in this regard. Defective regions on the mask can be reduced e.g. by means of a mask correction and/or by means of an adaptation of lithographic parameters in the lithography.

FIG. 1A shows in this respect a first standard solution S from a known mask inspection system. Two aerial images are illustrated in FIG. 1A. The left-hand part of FIG. 1A illustrates a first aerial image I having a defective region. The defective region can comprise e.g. the relatively small lower box in the first aerial image I, it being assumed before an examination that the dimensions of the box are not within specification. This may have come about e.g. as a result of an upstream examination of the mask. However, the upstream examination need not necessarily have used a mask inspection system in which the optical constraints were realized as in the case of lithography. The right-hand part of FIG. 1A illustrates a reference aerial image R comprising the same structure as the first aerial image, but it is known here that no defective region is present in the aerial image. The reference aerial image R may thus serve as a “defect-free” reference.

The reference aerial image R and the first aerial image I may be e.g. aerial images of the same mask that is examined using the mask inspection system. It is customary to apply the structures for two or more dies on a mask, such that two or more die structures can be produced simultaneously during the lithography. A die architecture can thus be repeated across the mask. This periodicity can be used for fault checking. By way of example, it may have been determined that a structure of a first die is faulty (e.g. the lower box in FIG. 1). In order to check the defect more closely, the same structure present on a different, second die may then be used as a reference if this same (corresponding) structure has been evaluated as non-faulty.

In the prior art, in such a case, the first (defective) aerial image I is compared with the reference aerial image R. In this case, for example, the CD in the defective region in the first (defective) aerial image I is compared with the CD in the corresponding non-defective region in the reference aerial image R. For this purpose, for example, a CD threshold value ascertainment may also take place on the basis of the reference aerial image.

In the prior art, this approach of comparing the reference aerial image R with a first (defective) aerial image may be effected e.g. automatically by software of the mask inspection system. This is particularly advantageous for the user of the mask inspection system since manual steps can be dispensed with, thereby reducing time and complexity.

However, the method from FIG. 1A can also be effected manually by an operator.

The approach from FIG. 1A is principally suitable for masks used for imaging a plurality of dies, since a “defect-free” reference is required.

However, single-die masks may also be present, these masks needing to be analysed for lithography. In the case of a single-die mask, only the architecture of one die is applied on the mask, and so only this one die can ever be imaged during lithography. Single-die masks are used for comparatively larger chips, for example. However, the method from FIG. 1A is not always suitable for single-die masks.

This is because the starting point for a single-die mask is that usually there is no corresponding reference point vis-à-vis the structure deemed to be faulty. A reason may be e.g. that a structure occurs only once on the die, in which case for a single-die mask no corresponding “defect-free” structure of a different die can then be used as a reference. Thus, for a single-die mask there may be a specially designed contact hole structure that is not repeated on the die itself. Consequently, there is no possibility of using a “defect-free” reference such as e.g. in the case of masks used for imaging a plurality of identically designed dies.

In this respect, FIG. 1B shows an exemplary approach known from the prior art for enabling single-die masks to be analysed. A single-die solution SD is thus shown.

In this case, the prior art hitherto has relied on a manual approach. The latter is time-intensive, however. Furthermore, faults may be caused more easily in a manual approach. The analysis of single-die masks is therefore not always optimal using this approach. A basic concept in the known method is to have recourse to the mask design of the mask. This necessitates manually having recourse to the mask design ML, and a comparison with the dimensions from the first (defective) aerial image I is then effected.

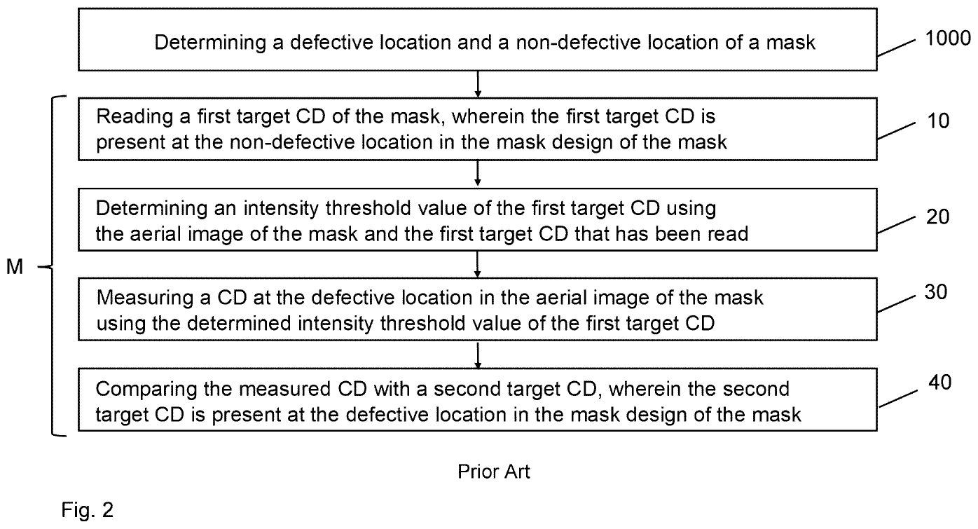

FIG. 2 shows in this respect an exemplary method from the prior art for analysing a mask by means of a CD measurement in accordance with the approach from FIG. 1B.

The method from the prior art for analysing a mask can firstly comprise the initial step of: determining 1000 a defective location 302 and a non-defective location 301 of a mask. For example, an optical method can be used to determine a defective location on the mask, wherein this corresponding location is marked in the aerial image of the mask. Finding suspicious, potentially faulty locations is known from the prior art, wherein any suitable methods can be used for this purpose. Furthermore, the mask design ML of the mask is used for the known approach, in which mask design likewise the defective location 302 and the non-defective location 301 are correspondingly present.

The method can then furthermore comprise the following steps: reading 10 a first target CD of the mask, wherein the first target CD is present at the non-defective location in the mask design of the mask; determining 20 an intensity threshold value of the first target CD using the aerial image of the mask and the first target CD that has been read; measuring 30 a CD at the defective location in the aerial image of the mask using the determined intensity threshold value of the first target CD; comparing 40 the measured CD with a second target CD, wherein the second target CD is present at the defective location in the mask design of the mask.

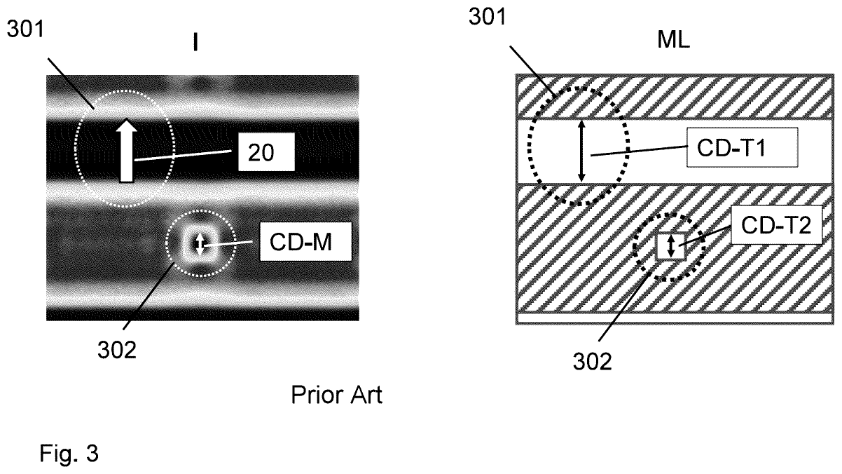

The procedure of the known method can be explained in greater detail by way of FIG. 3.

In this regard, FIG. 3 schematically shows the method from the prior art from FIG. 2. In FIG. 3, the left-hand partial illustration depicts the aerial image I to be examined. The right-hand partial illustration depicts the corresponding segment from the mask design ML.

By means of step 1000, firstly a non-defective location 301 and a defective location 302 are detected in the aerial image I. The non-defective location can be determined e.g. manually by the operator. The locations 301, 302 are likewise correspondingly detected in the mask design, as evident in the right-hand partial illustration in FIG. 3.

In the step of reading 10, a first target CD CD-T1 of the mask is then read, wherein the first target CD CD-T1 is present at the non-defective location 301 in the mask design of the mask (as evident in the right-hand partial illustration in FIG. 3). In this example, a line width representing the target CD CD-T1 is deduced.

This is followed by determining 20 the intensity threshold value of the first target CD CD-T1 using the aerial image I of the mask and the first target CD CD-T1 that has been read. Determining the intensity threshold value can be determining a CD threshold value as known in the field of lithography.

By way of example, it can be assumed that, in the ideal case, the target CD CD-T1 is present at the non-defective location 301 in the aerial image I as well. A CD threshold value can then be determined using this assumption. As described, the CD threshold value can be an intensity threshold as of which the CD begins or ends. It is thus assumed that the target CD CD-T1 of the mask design is reflected in the CD of the non-defective region 301 in the aerial image I. On the basis thereof, it is therefore possible to determine the intensity as of which that can be called structure formation in the aerial image, which is represented by the CD threshold value.

The determination of the CD threshold value can then enable the measurement of a CD in the aerial image, since the intensity threshold as of which a CD begins or ends is not always known beforehand. Put simply, the steps of reading 10 and determining 20 can be regarded as calibration steps that enable a reliable CD measurement.

In accordance with the known method, therefore, the step of measuring 30 then involves measuring the CD CD-M at the defective location 302 in the aerial image I of the mask using the intensity threshold value on the basis of the first target CD CD-T1. The previous steps have revealed that the intensity threshold value for the measurement at the defective location is also the same intensity threshold value as in the case of a defect-free location. The measurement at the defective location 302 is thus based on the same conditions that also exist at the defect-free location 301 (that is to say that the CD does not actually begin until starting from a specific intensity threshold value).

This is followed by comparing 40 the measured CD CD-M with the target CD CD-T2 at the defective location 302 in the mask design of the mask. In the ideal case it should be assumed (as at the defect-free location 301) that the target CD CD-T2 at the defective location 302 also corresponds to the measured CD CD-M. Since this is a defective location 302, however, there may be a deviation between measured CD CD-M and target CD CD-T2, which deviation is determined by way of the comparing. The determination of the CD threshold value by way of the defect-free location 301 ensures that the possible deviation in relation to non-defective locations can be reliably determined.

However, steps 10, 20, 30, 40 of the known method mentioned have to be effected manually by the operator (marked as manually M in FIG. 2). In this regard, for example, the operator needs to have the mask design and the aerial image displayed (for example by means of a computer with a monitor with a corresponding computer program). The aforementioned CDs then have to be determined manually, e.g. by means of corresponding manual inputs in the computer program or the manual triggering of measurements. The intensity threshold value, too, has hitherto had to be determined manually by the operator, e.g. by retrieval of corresponding intensities at the aforementioned positions or by the manual triggering of corresponding measurements.

However, the manual steps 10, 20, 30, 40 make the method very time-intensive and complex, as well as susceptible to errors.

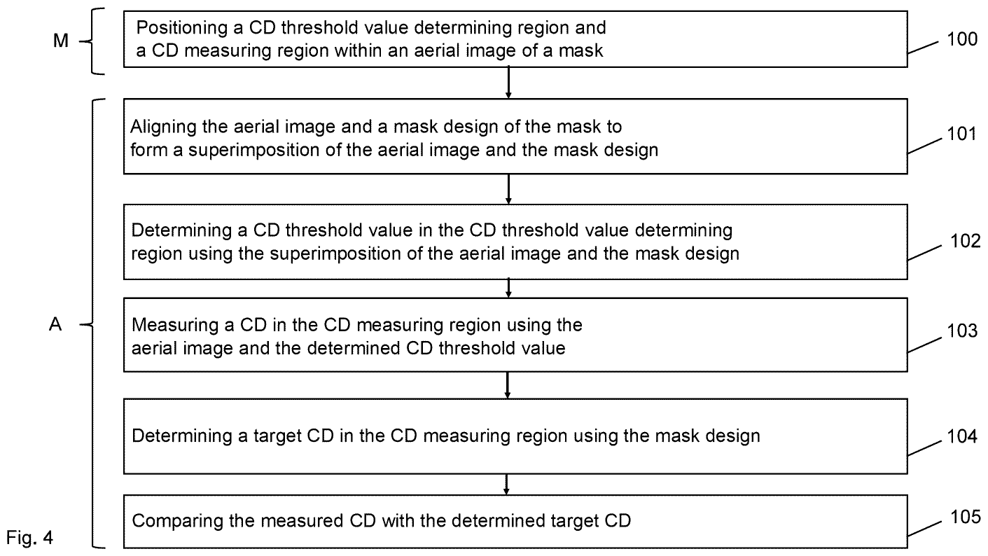

FIG. 4 shows an exemplary method for analysing a mask in accordance with the disclosure described herein. This method can at least partly reduce the disadvantages of the prior art described. In this case, FIG. 4 shows a specific application example of the method in accordance with the disclosure described herein.

The exemplary method from FIG. 4 shows in particular the following steps: positioning 100 a CD threshold value determining region and a CD measuring region within an aerial image of a mask; aligning 101 the aerial image and a mask design of the mask to form a superimposition of the aerial image and the mask design; determining 102 a CD threshold value in the CD threshold value determining region using the superimposition of the aerial image and the mask design; measuring 103 a CD in the CD measuring region using the aerial image and the determined CD threshold value; determining 104 a target CD in the CD measuring region with use of the mask design (of the superimposition); comparing 105 the measured CD with the determined target CD.

The step of positioning 100 the CD threshold value determining region and the CD measuring region within the aerial image of the mask is effected manually (marked by manually M in FIG. 4).

The other steps, however, are then effected automatically: aligning 101, determining 102 the CD threshold value, measuring 103 the CD in the CD measuring region; determining 104 the target CD in the CD measuring region, comparing 105 the measured CD with the determined CD (marked with automatically A in FIG. 4).

The operator therefore only needs to define the CD threshold value determining region and the CD measuring region. In this case, the CD measuring region may comprise a defective location, in particular. The CD of a defective location is thus intended to be measured in the CD measuring region. The CD threshold value determining region may comprise a non-defective location, in particular. The CD threshold value determining region may thus serve as a reference used for determining the CD threshold value. The latter is then used for the measurement in the CD measuring region.

This manual step is subsequently followed by a completely automated solution which then provides the operator with the CD in the CD measuring region, and also a comparison of this CD with the corresponding target CD that would be desired in this region.

The method in accordance with the disclosure described herein can be applied to single-die masks, in particular, which do not always have a suitable reference structure like other masks (as explained herein).

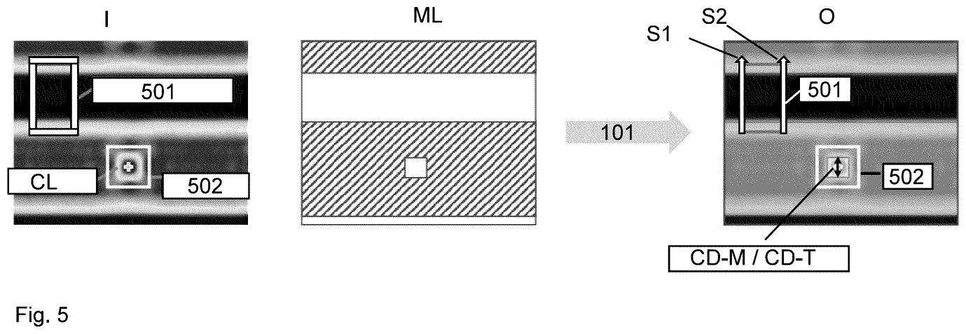

The procedure of the method will now be explained in greater detail with reference to FIG. 5, which schematically illustrates the method from FIG. 4.

In FIG. 5, the left-hand partial illustration firstly depicts the aerial image I with a defective location CL. By way of example, the defective location CL may be an imaging of a contact hole structure that does not conform to the specification. The defective location CL may e.g. have been determined beforehand using conventional lithographic means (as described herein).

In accordance with the method described herein, the operator firstly has to position the CD threshold value determining region 501 within the aerial image I. This takes place at a location at which no defect is present. This may e.g. be previously known (e.g. as a result of a preceding inspection that only indicates the faults, such as the defective location CL). Furthermore, in this case, the operator can also manually choose a suitable location that they consider to be non-defective.

The operator secondly also has to position the CD measuring region 502 within the aerial image. This takes place e.g. at a location at which a defect CL is present. By way of example, the CD measuring region 502 can be positioned such that the defective location CL (in this example the defective contact hole structure) is situated within the CD measuring region 502. The CD measuring region can be chosen such that it precisely encloses the defective location CL in order to facilitate the CD measurement.

For the positioning of the CD measuring region, e.g. an alignment marker (e.g. a cross) can also be displayed besides the actual CD measuring region.

These manual steps can be effected e.g. with the aid of a monitor and an input unit, which are coupled to a computing unit, on which a computer program runs according to the method described herein. In this case, the operator merely has to position the CD threshold value determining region 501 and the CD measuring region 502 with the aid of the computer program. The rest of the method proceeds in an automated manner. The monitor, the input unit and/or the computing unit may e.g. also be part of a mask inspection system.

In the context of the automated part, firstly (before the manual step 100) the aerial image I and also the corresponding segment of the mask design ML may have been loaded.

As mentioned, the CD measuring region 502 and the CD threshold value determining region 501 are then positioned manually in the aerial image. The other steps are then effected automatically.

In this regard, the positioning is followed firstly by aligning the aerial image I and the mask design ML of the mask to form a superimposition of the aerial image and the mask design (as described herein). In this case, e.g. a spatial superimposition can take place, such that corresponding points and values from the aerial image I can be assigned to corresponding points and values from the mask design. As a result of the superimposition, e.g. at a position X1, Y1 in the aerial image I with an intensity value I_{x1,y1} it is possible to effect an assignment to a (colour) coding C_{x1,y1} that is present at correspondingly the same position X1, Y1 in the mask design. As mentioned, the colour coding may e.g. indicate whether an absorbing or a non-absorbing material should be present at the location in the mask design.

The superimposition of the aerial image I and the mask design ML is depicted as a superimposition O in the right-hand partial illustration in FIG. 5.

This is followed by automatically determining the CD threshold value in the CD threshold value determining region 501 using the superimposition of the aerial image and the mask design. As described herein, for this purpose it is possible to determine a transition position at which a transition from an imaging structure to a non-imaging structure takes place in the mask design. For this purpose, it is possible to define e.g. one or more lines in the CD threshold value determining region along which the intensity profile is determined, wherein the corresponding transition positions of the mask design are correlated therewith. The superimposition makes it possible to determine in particular the intensity of the aerial image at the transition position, which can be used for determining the CD threshold value.

By way of example, FIG. 5 depicts two lines, a first line S1 (a first “slice”) and a second line S2 (a second “slice”). The first line S1 and the second line S2 each intersect at least one transition position in the mask design. With regard to the superimposition, two items of information along the corresponding spatial axis would thus be present for a line. Firstly, there would be the intensity profile of the aerial image along said spatial axis. Secondly, there would be the coding of the mask design along said spatial axis, from which the transition from an imaging structure to a non-imaging structure can be determined.

These items of information can be used to determine the intensity of the aerial image at the transition position, which intensity can be regarded as a CD threshold value. It can thus be assumed that in the CD threshold value determining region the CD of the mask design is also reflected in the aerial image, since the CD threshold value measuring region only comprises a non-defective location.

Furthermore, for an intersection line it is also possible to use more complex approaches in order to determine the CD threshold value. By way of example, for two transition positions over an intersection line it is possible to average the corresponding CD threshold values of the respective transition positions of the same intersection line.

Likewise, with use of two or more intersection lines (as in FIG. 5), it is possible firstly to determine CD threshold values for each intersection line. A first CD threshold value for the first line S1 and a second CD threshold value for the second line S2 would thus be determined in this case. The respective CD threshold values of the intersection lines can subsequently be averaged.

The average value of the first CD threshold value of the first line S1 and the second CD threshold value of the second line S2 would thus be formed in this example.

As described herein, it is also possible to use more than two lines for the determination of the CD threshold value.

In summary, the CD threshold value is determined by way of the CD threshold value determining region in the automated part.

In step 103 (measuring the CD in the measuring region), this CD threshold value is used to measure the CD in the CD measuring region by way of the aerial image (as described herein). The CD threshold value thus reveals as of when the CD begins or ends. In this case, it is possible to have recourse to the aerial image part from the superimposition O. Furthermore, it is also conceivable to have recourse to the aerial image I itself.

The measured CD is indicated schematically as CD-M in FIG. 5.

Furthermore, the method comprises the step of determining 104 a target CD in the CD measuring region using the mask design. This step need not necessarily take place after step 103, but rather can also precede the latter.

The target CD in the CD measuring region is indicated schematically as CD-T in FIG. 5.

For the target CD, this involves having recourse to the dimension of the defective location CL (e.g. the dimension of the contact hole structure) in the mask design. The data of the mask design thus assist in determining what target CD should be present in the defective region 502 according to the mask design. For this purpose, it is possible to have recourse to the mask design part from the superimposition O. Furthermore, it is also conceivable to have recourse to the mask design ML itself.

In summary, two items of information are thus present. Firstly, the measured CD CD-M from the CD measuring region 502, which was determined with the aid of the CD threshold value from the CD threshold value determining region 501. Secondly, the target CD CD-T in the CD measuring region 502 according to the mask design.

Afterwards, in the automated method, the measured CD CD-M can be compared with the target CD CD-T. By way of example, the deviation of the measured CD CD-M from the target CD CD-T can be determined in the context of the comparison.

It is thus possible e.g. to determine whether the deviation of the measured CD CD-M is still within the scope of a predefined specification.

The result of the comparison can subsequently be presented (e.g. on the monitor on which the operator had carried out the manual step 100, or by way of the generation of a corresponding digital report).

With the present approach in accordance with the disclosure described herein, the operator can thus dispense with numerous manual steps. The operator merely has to manually define the relevant areas. The calculation and evaluation with regard to the CD subsequently take place automatically.

Consequently, the analysis of a mask (in particular of a single-die mask) can be at least partly improved. This is because the approach described herein makes it possible to minimize the processing time on account of the reduction of the manual steps.

Furthermore, the susceptibility to errors and the complexity during the analysis can be reduced.

Other embodiments, features, and advantages are within the scope of the following claims.

### LIST OF REFERENCE SIGNS

S Standard solution
I Aerial image
R Reference aerial image
SD Single-die solution
ML Mask design
A automatically
301 Non-defective location
302 Defective location
CD-T1 First target CD
CD-T2 Second target CD
CD-M Measured CD
501 CD threshold value determining region
CL Defective location
502 CD measuring region
S1 First line
S2 Second line
CD-T Target CD

What is claimed is:

1. A method for analysing a mask for lithography, comprising:
aligning an aerial image of the mask and a mask design of the mask to form a superimposition of the aerial image and the mask design,
wherein a CD threshold value determining region and a CD measuring region are positioned within the aerial image;
determining a CD threshold value in the CD threshold value determining region using the superimposition of the aerial image and the mask design; and
measuring a critical dimension in the CD measuring region using the aerial image and the determined CD threshold value.

2. The method of claim 1, furthermore comprising:
determining a target CD in the CD measuring region using the mask design;
comparing the measured CD with the determined target CD.

3. The method of claim 2, furthermore comprising:
positioning the CD threshold value determining region and the CD measuring region within the aerial image;
wherein the CD threshold value determining region is positioned such that a non-defective location of the mask is present in the CD threshold value determining region;
wherein the CD measuring region is positioned such that a defective location of the mask is present in the CD measuring region;
wherein measuring the critical dimension comprises measuring a dimension of the defective location.

4. The method of claim 3, wherein positioning the CD threshold value determining region and the CD measuring region within the aerial image is effected manually by an operator.

5. The method of claim 4, wherein for positioning the CD threshold value determining region and the CD measuring region within the aerial image, firstly determining the defective location and the non-defective location is effected manually by an operator.

6. The method of claim 5, wherein after positioning the CD threshold value determining region and the CD measuring region, the following steps are effected automatically:
aligning the aerial image (I) of the mask and the mask design (ML);
determining the CD threshold value;
measuring the critical dimension.

7. The method of claim 6, referring back to claim 2, wherein after positioning the CD threshold value region and the CD measuring region, the following steps are furthermore effected automatically:
determining the target CD in the CD measuring region;
comparing the measured CD with the determined target CD.

8. The method of claim 7, wherein after positioning the CD threshold value determining region and the CD measuring region, manually confirming the positioning is effected by the operator, wherein the automatic steps are started by the confirming.

9. The method of claim 1, wherein determining the CD threshold value comprises:
determining at least one transition position of the mask design at which there is a transition from an imaging structure to a non-imaging structure of the mask;
determining an intensity of the aerial image at the transition position;
wherein the CD threshold value is at least partly based on the intensity of the aerial image at the at least one transition position.

10. The method of claim 1, wherein determining the CD threshold value comprises:
determining a first intensity profile of the aerial image (I) along a first line in the CD threshold value determining region;
wherein along the first line there is at least one transition position of the mask design at which there is a transition from an imaging structure to a non-imaging structure of the mask;
determining a first CD threshold value at least partly on the basis of an intensity of the first intensity profile at the at least one transition position of the first line.

11. The method of claim 10, wherein determining the CD threshold value furthermore comprises:
determining a second intensity profile of the aerial image along a second line in the CD threshold value determining region;
wherein the second line differs from the first line;
wherein along the second line in the mask design there is at least one transition position of the mask design at which there is a transition from an imaging structure to a non-imaging structure of the mask;
determining a second CD threshold value at least partly on the basis of an intensity of the second intensity profile at the at least one transition position of the second line.

12. The method of claim 11, wherein determining the CD threshold value furthermore comprises:
calculating an average value from the first and second CD threshold values, wherein the average value is determined as the CD threshold value.

13. The method of claim 1, wherein determining the CD threshold value comprises:
determining intensity profiles of the aerial image along at least three lines in the CD threshold value determining region;
wherein the lines differ from one another;
wherein in each case along a line in the mask design there is at least one transition position of the mask design at which there is a transition from an imaging structure to a non-imaging structure of the mask;
determining a respective CD threshold value for a respective line at least partly on the basis of an intensity of the respective intensity profile at the at least one transition position of the respective line.

14. The method of claim 13, wherein determining the CD threshold value comprises determining intensity profiles of the aerial image (I) at least along four, five, ten, twenty or one hundred lines in the CD threshold value determining region.

15. The method of claim 13, wherein determining the CD threshold value furthermore comprises:
calculating an average value from the respective CD threshold values of the different lines, wherein the average value is determined as the CD threshold value.

16. The method of claim 1, wherein measuring the critical dimension, CD, comprises:
determining a distance between two characteristic points of the aerial image (I) in the CD measuring region, wherein the intensity at the points substantially corresponds to the CD threshold value.

17. The method of claim 1, wherein the mask comprises a single-die mask, such that a die can be imaged in an imaging plane during a lithographic exposure of the mask.

18. The method of claim 2, wherein comparing the measured CD with the determined target CD (CD-T) is followed by automatically generating a report representing a summary of the method.

19. The method of claim 1, wherein the mask comprises a mask for DUV lithography and/or EUV lithography.

20. A computer program comprising instructions for executing a method according to claim 1.

21. A device for analysing a mask comprising a computing unit, wherein the computing unit is configured to execute a method according to claim 1.

22. The device of claim 21, furthermore comprising a memory, wherein the memory comprises a computer program configured to cause the computing unit to execute the method.

23. A system for analysing a mask for lithography, comprising:
a first unit for generating an aerial image of the mask, which aerial image can be present during the lithography of the mask;
a second unit for storing a mask design of the mask;
a third unit comprising a computing unit, wherein the computing unit is configured to execute a method according to claim 1;
wherein the first unit and the second unit are each communicatively coupled to the third unit, such that the third unit can receive and/or retrieve the aerial image and the mask design.

24. A system of claim 23, wherein the third unit furthermore comprises a memory, wherein the memory comprises a computer program configured to cause the computing unit to execute the method.
